(19) United States
(12) Patent Application Publication
(10) Pub. No.: US 2025/0071991 A1
(43) Pub. Date: Feb. 27, 2025

(54) SEMICONDUCTOR DEVICE AND ELECTRONIC SYSTEM INCLUDING THE SAME

(71) Applicant: Samsung Electronics Co., Ltd., Suwon-si (KR)

(72) Inventors: Sangwoo HAN, Suwon-si (KR); Jongho WOO, Suwon-si (KR); Seung Min LEE, Suwon-si (KR); Moonkang CHOI, Suwon-si (KR)

(73) Assignee: Samsung Electronics Co., Ltd., Suwon-si (KR)

(21) Appl. No.: 18/583,121

(22) Filed: Feb. 21, 2024

(30) Foreign Application Priority Data
Aug. 24, 2023 (KR) 10-2023-0111412

(51) Int. Cl. H10B 43/27; H01L 25/065; H10B 43/10; H10B 43/35; H10B 51/10; H10B 51/20; H10B 80/00

(52) U.S. Cl. CPC H10B 43/27; H01L 25/0652; H10B 43/10; H10B 43/35; H10B 51/10; H10B 51/20; H10B 80/00; H01L 2225/0651

(57) ABSTRACT

A semiconductor device includes a source structure comprising a first source layer, a second source layer on the first source layer, and a third source layer on the second source layer, a gate stack structure on the source structure, the gate stack structure with alternating insulating patterns and conductive patterns, and a memory channel structure penetrating the gate stack structure. The memory channel structure includes a channel layer and a memory layer surrounding the channel layer. The channel layer penetrates the memory layer and the second source layer, and a bottom surface of the channel layer is in contact with the source structure.

### CROSS-REFERENCE TO RELATED APPLICATIONS

This U.S. non-provisional patent application claims priority under 35 U.S.C. § 119 to Korean Patent Application No. 10-2023-0111412, filed on Aug. 24, 2023, in the Korean Intellectual Property Office, the entire contents of which are hereby incorporated by reference.

### BACKGROUND

The present disclosure relates to semiconductor devices and/or electronic systems including the same, and more particularly, to semiconductor devices including a channel layer which penetrates a memory layer and is in contact with a source structure, and/or electronic systems including the same.

Semiconductor devices are widely used in the electronic industry because of their small-sized, multi-functional and/or low-cost characteristics. Semiconductor devices may be categorized as any one of semiconductor memory devices for storing logical data, semiconductor logic devices for processing logical data, and hybrid semiconductor devices having both the function of the semiconductor memory devices and the function of the semiconductor logic devices.

As high-speed and/or low-power electronic devices have been demanded, high-speed and/or low-voltage semiconductor devices used therein have also been demanded, and highly integrated semiconductor devices have been required to satisfy these demands. However, as the integration densities of semiconductor devices increase, electrical characteristics and production yields of the semiconductor devices may be deteriorated or reduced. Thus, techniques for improving electrical characteristics and production yields of semiconductor devices have been variously studied.

### SUMMARY

Some example embodiments of the inventive concepts may provide semiconductor devices with improved electrical characteristics and reliability and/or electronic systems including the same.

According to an example embodiment, a semiconductor device may include a source structure comprising a first source layer, a second source layer on the first source layer, and a third source layer on the second source layer, a gate stack structure on the source structure, the gate stack structure with alternating insulating patterns and conductive patterns which are alternately stacked, and a memory channel structure penetrating the gate stack structure. The memory channel structure may include a channel layer and a memory layer surrounding the channel layer. The channel layer may penetrate the memory layer and the second source layer, and a bottom surface of the channel layer may be in contact with the source structure.

According to an example embodiment, a semiconductor device may include a source structure comprising a first source layer, a second source layer on the first source layer, and a third source layer on the second source layer, a gate stack structure on the source structure, the gate stack structure with alternating insulating patterns and conductive patterns, and a memory channel structure penetrating the gate stack structure. The memory channel structure may include a channel layer and a memory layer surrounding the channel layer. The channel layer may include an interposed portion protruding toward the third source layer, and a bottom surface spaced apart from the memory layer.

According to an example embodiment, an electronic system may include a main board, a semiconductor device on the main board, and a controller electrically connected to the semiconductor device on the main board. The semiconductor device may include a source structure comprising a first source layer, a second source layer on the first source layer, and a third source layer on the second source layer, a gate stack structure on the source structure, the gate stack structure with alternating insulating patterns and conductive patterns, a memory channel structure penetrating the gate stack structure, and a separation structure spaced apart from the memory channel structure. The memory channel structure may include a channel layer and a memory layer surrounding the channel layer. The memory layer may include a tunnel insulating layer, a data storing layer surrounding the tunnel insulating layer, and a blocking layer surrounding the data storing layer. A level of a bottom surface of the memory layer may be higher than a level of a bottom surface of the separation structure.

### BRIEF DESCRIPTION OF THE DRAWINGS

FIG. 1A is a schematic view illustrating an electronic system including a semiconductor device according to an example embodiment of the inventive concepts.

FIG. 1B is a perspective view schematically illustrating an electronic system including a semiconductor device according to an example embodiment of the inventive concepts.

FIGS. 1C and 1D are cross-sectional views schematically illustrating semiconductor packages according to some example embodiments of the inventive concepts.

FIG. 2A is a plan view illustrating a semiconductor device according to an example embodiment of the inventive concepts.

FIG. 2B is a cross-sectional view taken along a line A-A′ of FIG. 2A.

FIG. 2C is an enlarged view of a region ‘E’ of FIG. 2B.

FIG. 3 is an enlarged view illustrating a semiconductor device according to an example embodiment of the inventive concepts.

FIGS. 4A, 4B, 5A, 5B, 6A, 6B, 7A, 7B, 8A, 8B, 9A, 9B, 10A and 10B are views illustrating a method of manufacturing a semiconductor device according to an example embodiment of the inventive concepts.

### DETAILED DESCRIPTION

Some example embodiments of the inventive concepts will now be described more fully with reference to the accompanying drawings.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

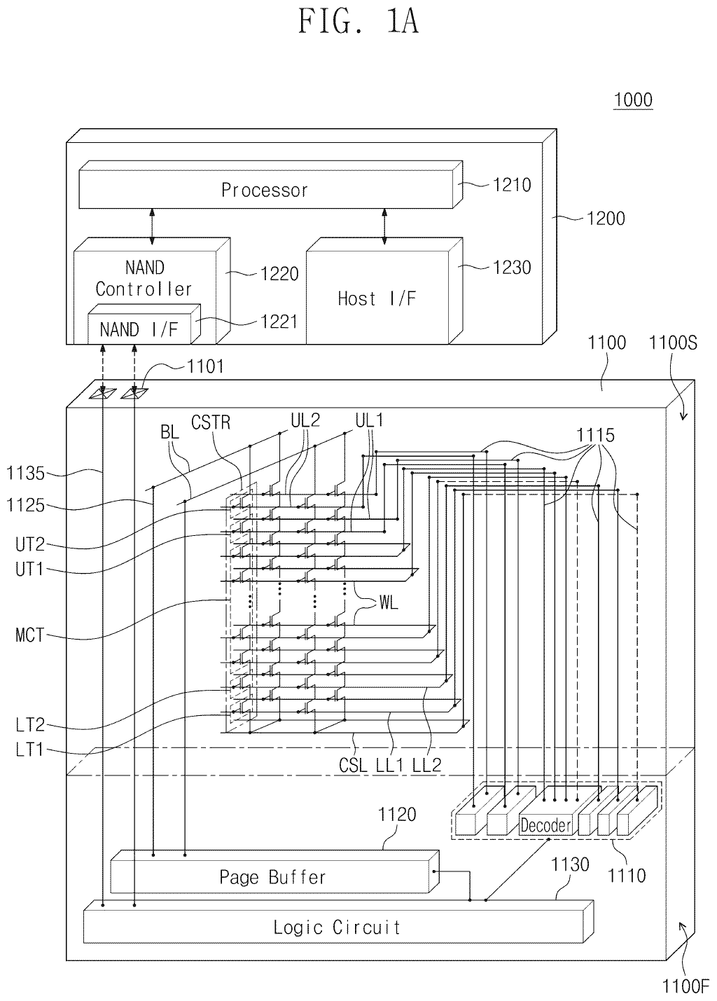

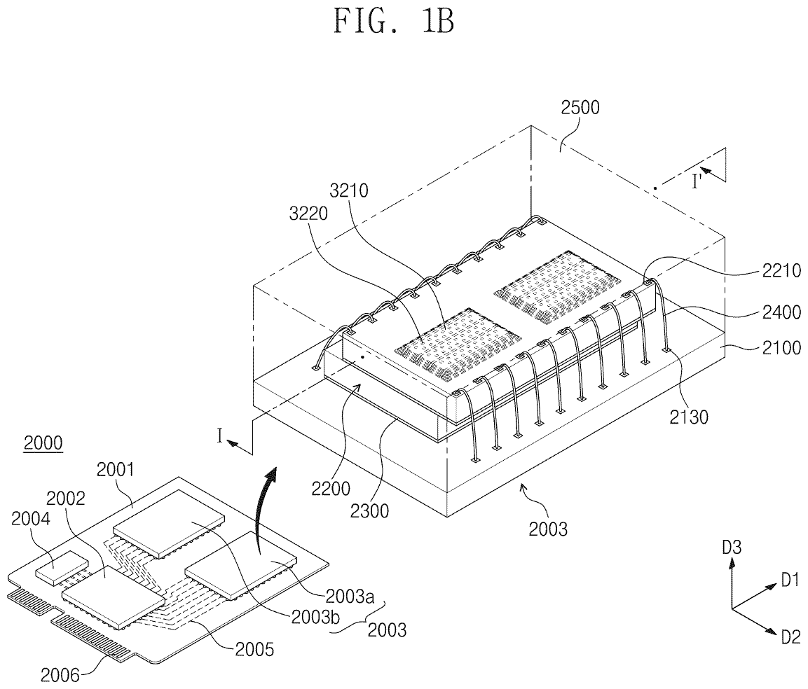

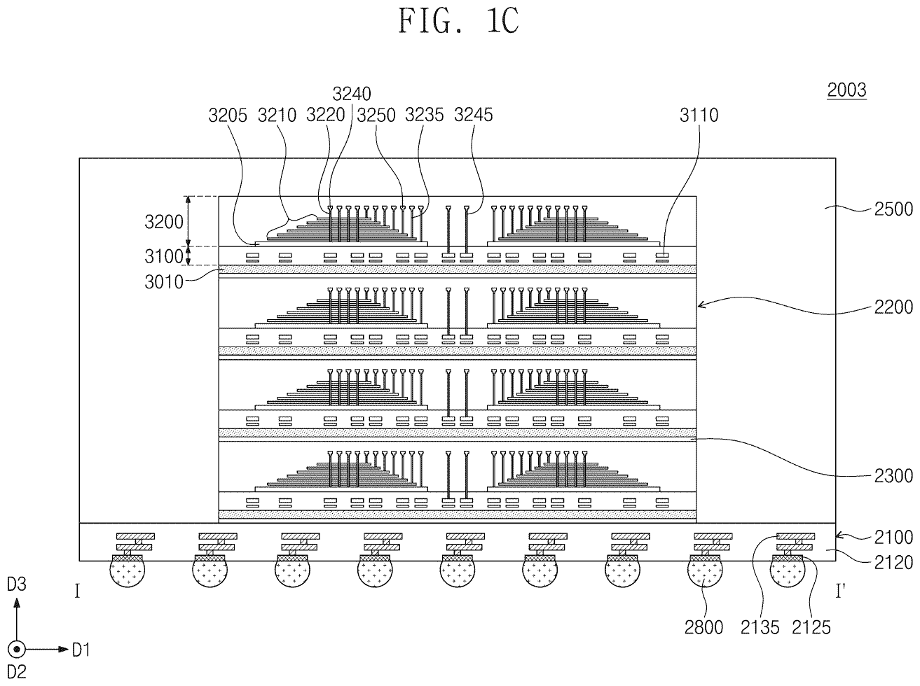

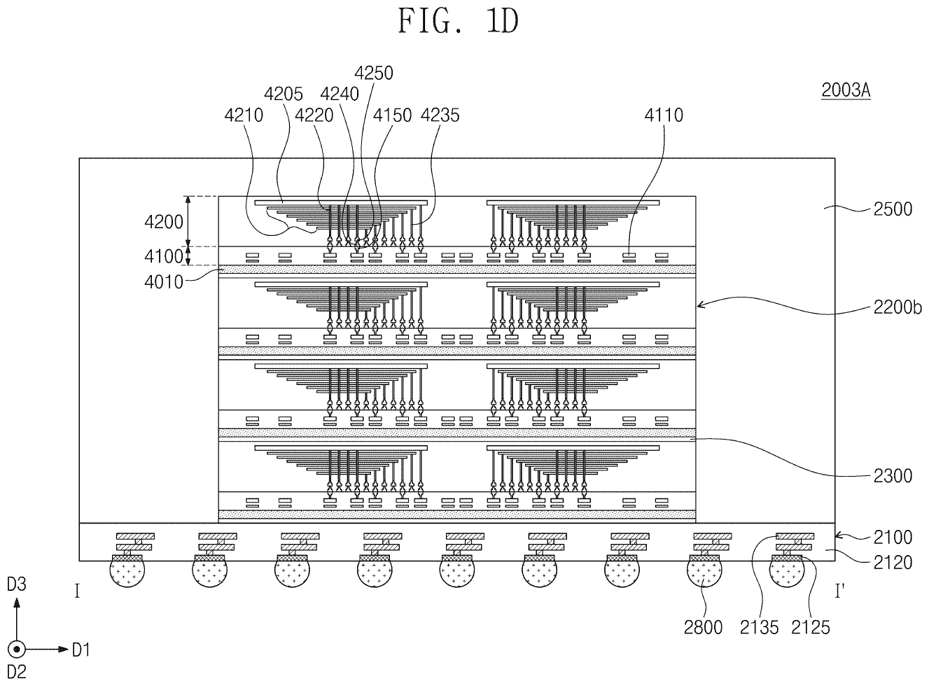

FIG. 1A is a schematic view illustrating an electronic system including a semiconductor device according to an example embodiment of the inventive concepts.

Referring to FIG. 1A, an electronic system 1000 according to s an example embodiment may include a semiconductor device 1100 and a controller 1200 electrically connected to the semiconductor device 1100. The electronic system 1000 may be a storage device including one or more semiconductor devices 1100, or an electronic device including the storage device. For example, the electronic system 1000 may be a solid state drive (SSD) device, a universal serial bus (USB) device, a computing system, a medical device or a communication device, which includes the one or more semiconductor devices 1100.

The semiconductor device 1100 may be a non-volatile memory device and may be, for example, a NAND flash memory device to be described later. The semiconductor device 1100 may include a first structure 1100F and a second structure 1100S on the first structure 1100F. In certain embodiments, the first structure 1100F may be disposed at a side of the second structure 1100S. The first structure 1100F may be a peripheral circuit structure including a decoder circuit 1110, a page buffer 1120, and a logic circuit 1130. The second structure 1100S may be a memory cell structure including bit lines BL, a common source line CSL, word lines WL, first and second gate upper lines UL1 and UL2, first and second gate lower lines LL1 and LL2, and memory cell strings CSTR between the bit lines BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of the lower transistors LT1 and LT2 and the number of the upper transistors UT1 and UT2 may be variously changed.

In some example embodiments, the upper transistors UT1 and UT2 may include a string selection transistor, and the lower transistors LT1 and LT2 may include a ground selection transistor. The gate lower lines LL1 and LL2 may be gate electrodes of the lower transistors LT1 and LT2, respectively. The word lines WL may be gate electrodes of the memory cell transistors MCT, and the gate upper lines UL1 and UL2 may be gate electrodes of the upper transistors UT1 and UT2, respectively.

The common source line CSL, the first and second gate lower lines LL1 and LL2, the word lines WL and the first and second gate upper lines UL1 and UL2 may be electrically connected to the decoder circuit 1110 through first connection lines 1115 extending from the first structure 1100F into the second structure 1100S. The bit lines BL may be electrically connected to the page buffer 1120 through second connection lines 1125 extending from the first structure 1100F into the second structure 1100S.

In the first structure 1100F, the decoder circuit 1110 and the page buffer 1120 may perform a control operation on at least one selected from the plurality of memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through an input/output connection line 1135 extending from the first structure 1100F into the second structure 1100S.

The controller 1200 may include a processor 1210, a NAND controller 1220, and a host interface 1230. In some embodiments, the electronic system 1000 may include a plurality of the semiconductor devices 1100, and in this case, the controller 1200 may control the plurality of semiconductor devices 1100.

The processor 1210 may control overall operations of the electronic system 1000 including the controller 1200. The processor 1210 may operate according to predetermined firmware and may control the NAND controller 1220 to access the semiconductor device 1100. The NAND controller 1220 may include a NAND interface 1221 for processing communication with the semiconductor device 1100. A control command for controlling the semiconductor device 1100, data to be written in the memory cell transistors MCT of the semiconductor device 1100 and data to be read from the memory cell transistors MCT of the semiconductor device 1100 may be transmitted through the NAND interface 1221. The host interface 1230 may provide a communication function between the electronic system 1000 and an external host. When the control command is received from the external host through the host interface 1230, the processor 1210 may control the semiconductor device 1100 in response to the control command.

FIG. 1B is a perspective view schematically illustrating an electronic system including a semiconductor device according to an example embodiment of the inventive concepts.

Referring to FIG. 1B, an electronic system 2000 according to an example embodiment may include a main board 2001, and a controller 2002, one or more semiconductor packages 2003 and a DRAM 2004 that are mounted on the main board 2001. The semiconductor package 2003 and the DRAM 2004 may be connected to the controller 2002 through wiring patterns 2005 formed at the main board 2001.

The main board 2001 may include a connector 2006 including a plurality of pins coupled to an external host. The number and arrangement of the plurality of pins in the connector 2006 may be changed according to a communication interface between the electronic system 2000 and the external host. In some example embodiments, the electronic system 2000 may communicate with the external host through one of a universal serial bus (USB) interface, a peripheral component interconnect express (PCI-express) interface, a serial advanced technology attachment (SATA) interface, and a M-Phy interface for a universal flash storage (UFS). In some example embodiments, the electronic system 2000 may operate by power supplied from the external host through the connector 2006. The electronic system 2000 may further include a power management integrated circuit (PMIC) for distributing the power supplied from the external host to the controller 2002 and the semiconductor package 2003.

The controller 2002 may write data in the semiconductor package 2003 and/or read data from the semiconductor package 2003 and may improve an operation speed of the electronic system 2000.

The DRAM 2004 may be a buffer memory for reducing a speed difference between the external host and the semiconductor package 2003 corresponding to a data storage space. The DRAM 2004 included in the electronic system 2000 may also operate as a cache memory and may provide a space for temporarily storing data in an operation of controlling the semiconductor package 2003. In the case in which the electronic system 2000 includes the DRAM 2004, the controller 2002 may further include a DRAM controller for controlling the DRAM 2004 in addition to a NAND controller for controlling the semiconductor package 2003.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chips 2200 on the package substrate 2100, adhesive layers 2300 disposed on bottom surfaces of the semiconductor chips 2200, respectively, a connection structure 2400 electrically connecting the semiconductor chips 2200 to the package substrate 2100, and a molding layer 2500 covering the semiconductor chips 2200 and the connection structure 2400 on the package substrate 2100.

The package substrate 2100 may be a printed circuit board including package upper pads 2130. Each of the semiconductor chips 2200 may include an input/output pad 2210. The input/output pad 2210 may correspond to the input/output pad 1101 of FIG. 1A. Each of the semiconductor chips 2200 may include gate stack structures 3210 and memory channel structures 3220. Each of the semiconductor chips 2200 may include a semiconductor device to be described later.

In some example embodiments, the connection structure 2400 may be a bonding wire electrically connecting the input/output pad 2210 to the package upper pad 2130. Thus, in each of the first and second semiconductor packages 2003a and 2003b, the semiconductor chips 2200 may be electrically connected to each other by the bonding wire method and may be electrically connected to the package upper pads 2130 of the package substrate 2100 by the bonding wire method. In certain embodiments, in each of the first and second semiconductor packages 2003a and 2003b, the semiconductor chips 2200 may be electrically connected to each other by a connection structure including a through-silicon via (TSV), instead of the connection structure 2400 having the bonding wire.

In some example embodiments, the controller 2002 and the semiconductor chips 2200 may be included in a single package. For example, the controller 2002 and the semiconductor chips 2200 may be mounted on an interposer substrate different from the main board 2001, and the controller 2002 and the semiconductor chips 2200 may be connected to each other by wiring lines formed at the interposer substrate.

FIGS. 1C and 1D are cross-sectional views schematically illustrating semiconductor packages according to some example embodiments of the inventive concepts. FIGS. 1C and 1D are cross-sectional views taken along a line I-I′ of FIG. 1B to illustrate some example embodiments of the semiconductor package of FIG. 1B.

Referring to FIG. 1C, in the semiconductor package 2003, the package substrate 2100 may be a printed circuit board. The package substrate 2100 may include a package substrate body portion 2120, the package upper pads 2130 (see FIG. 1B) disposed on a top surface of the package substrate body portion 2120, package lower pads 2125 disposed on or exposed at a bottom surface of the package substrate body portion 2120, and internal wiring lines 2135 disposed in the package substrate body portion 2120 to electrically connect the package upper pads 2130 to the package lower pads 2125. The package upper pads 2130 may be electrically connected to the connection structures 2400 (see FIG. 1B). The package lower pads 2125 may be connected to the wiring patterns 2005 of the main board 2001 of the electronic system 2000 through conductive connection portions 2800, as illustrated in FIG. 1B.

Each of the semiconductor chips 2200 may include a semiconductor substrate 3010, and a first structure 3100 and a second structure 3200 which are sequentially stacked on the semiconductor substrate 3010. The first structure 3100 may include a peripheral circuit region including peripheral interconnection lines 3110. The second structure 3200 may include a common source line 3205, a gate stack structure 3210 on the common source line 3205, memory channel structures 3220 penetrating the gate stack structure 3210, bit lines 3240 electrically connected to the memory channel structures 3220, and gate contact plugs 3235 electrically connected to word lines WL (see FIG. 1A) of the gate stack structure 3210.

Each of the semiconductor chips 2200 may include a through-interconnection line 3245 which is electrically connected to the peripheral interconnection line 3110 of the first structure 3100 and extends into the second structure 3200. The through-interconnection line 3245 may be disposed outside the gate stack structure 3210. In certain example embodiments, the through-interconnection line 3245 may penetrate the gate stack structure 3210. Each of the semiconductor chips 2200 may further include the input/output pad 2210 (see FIG. 1B).

Referring to FIG. 1D, in a semiconductor package 2003A, each of semiconductor chips 2200b may include a semiconductor substrate 4010, a first structure 4100 on the semiconductor substrate 4010, and a second structure 4200 disposed on the first structure 4100 and bonded to the first structure 4100 by a wafer bonding method.

The first structure 4100 may include a peripheral circuit region including peripheral interconnection lines 4110 and first bonding structures 4150. The second structure 4200 may include a common source line 4205, a gate stack structure 4210 between the common source line 4205 and the first structure 4100, memory channel structures 4220 penetrating the gate stack structure 4210, bit lines 4240 electrically connected to the memory channel structures 4220, gate contact plugs 4235 electrically connected to word lines WL (see FIG. 1A) of the gate stack structure 4210, respectively, and second bonding structures 4250. For example, the second bonding structures 4250 may be electrically connected to the memory channel structures 4220 through the bit lines 4240 electrically connected to the memory channel structures 4220. The first bonding structures 4150 of the first structure 4100 may be bonded to the second bonding structures 4250 of the second structure 4200. For example, bonded portions of the first bonding structures 4150 and the second bonding structures 4250 may be formed of copper (Cu). Each of the semiconductor chips 2200b may further include the input/output pad 2210 (see FIG. 1B).

The semiconductor chips 2200 of FIG. 1C or the semiconductor chips 2200b of FIG. 1D may be electrically connected to each other through the connection structures 2400 (see FIG. 1B) having the bonding wire shapes. In certain example embodiments, semiconductor chips (e.g., the semiconductor chips 2200 of FIG. 1C or the semiconductor chips 2200b of FIG. 1D) in a single semiconductor package may be electrically connected to each other through connection structures including through-silicon vias (TSV).

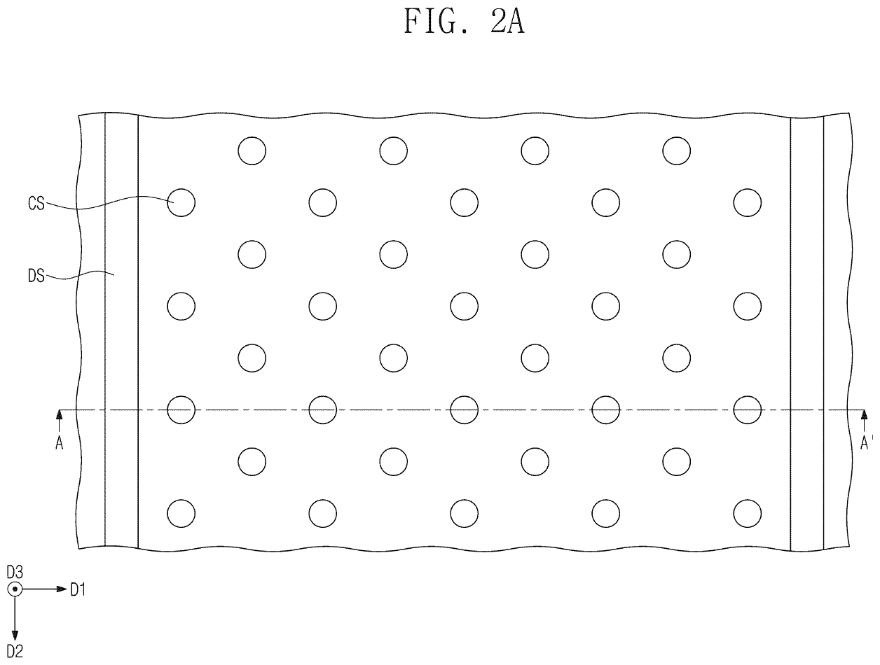

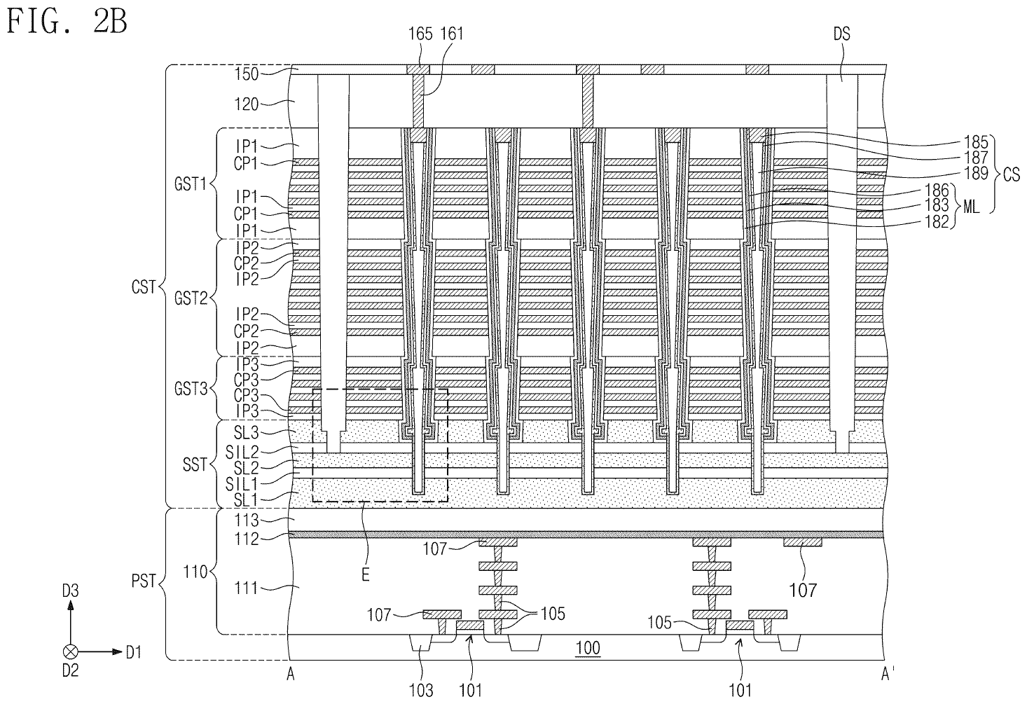

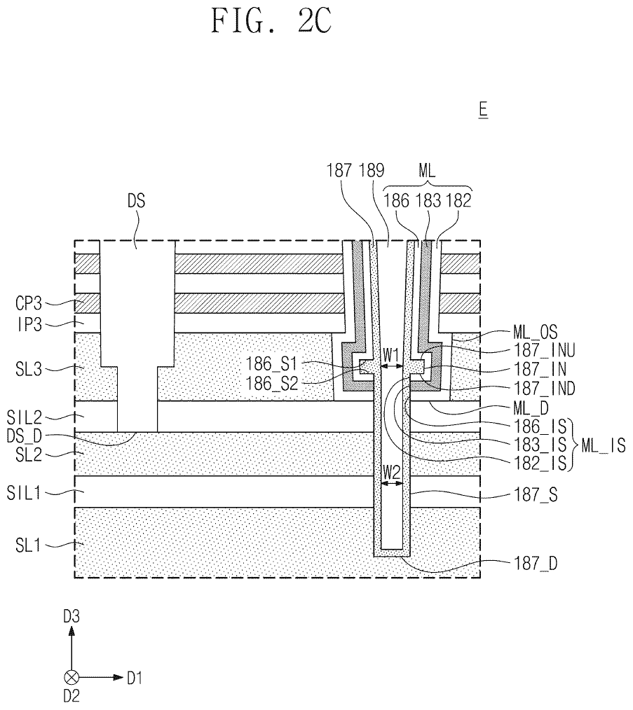

FIG. 2A is a plan view illustrating a semiconductor device according to an example embodiment of the inventive concepts. FIG. 2B is a cross-sectional view taken along a line A-A′ of FIG. 2A. FIG. 2C is an enlarged view of a region ‘E’ of FIG. 2B.

Referring to FIGS. 2A, 2B and 2C, a semiconductor device may include a peripheral circuit structure PST and a memory cell structure CST on the peripheral circuit structure PST.

The peripheral circuit structure PST may include a substrate 100. The substrate 100 may have a plate shape extending along a plane defined by a first direction D1 and a second direction D2. The first direction D1 and the second direction D2 may intersect each other. For example, the first direction D1 and the second direction D2 may be horizontal directions perpendicular to each other. In some example embodiments, the substrate 100 may be a semiconductor substrate. For example, the substrate 100 may include silicon, germanium, silicon-germanium, GaP, or GaAs. In certain example embodiments, the substrate 100 may be a silicon-on-insulator (SOI) substrate or a germanium-on-insulator (GOI) substrate.

The peripheral circuit structure PST may include a peripheral circuit insulating structure 110 on the substrate 100. The peripheral circuit insulating structure 110 may include a first peripheral circuit insulating layer 111, a second peripheral circuit insulating layer 112 on the first peripheral circuit insulating layer 111, and a third peripheral circuit insulating layer 113 on the second peripheral circuit insulating layer 112. The first to third peripheral circuit insulating layers 111, 112 and 113 may include insulating materials. For example, the first and third peripheral circuit insulating layers 111 and 113 may include an oxide, and the second peripheral circuit insulating layer 112 may include a nitride. In certain example embodiments, each of the first to third peripheral circuit insulating layers 111, 112 and 113 may be a multi-layered insulating layer.

The peripheral circuit structure PST may further include a peripheral transistor 101. The peripheral transistor 101 may be provided between the substrate 100 and the peripheral circuit insulating structure 110. In some example embodiments, the peripheral transistor 101 may include source/drain regions, a gate electrode, and a gate insulating layer. Device isolation layers 103 may be provided in the substrate 100. The peripheral transistor 101 may be disposed between the device isolation layers 103. The device isolation layer 103 may include an insulating material.

The memory cell structure CST may include a source structure SST, a first gate stack structure GST1, a second gate stack structure GST2, a third gate stack structure GST3, memory channel structures CS, separation structures DS, bit line contacts 161, and bit lines 165.

The source structure SST may include a first source layer SL1 on the peripheral circuit structure PST, a first source insulating layer SIL1 on the first source layer SL1, a second source layer SL2 on the first source insulating layer SIL1, a second source insulating layer SIL2 on the second source layer SL2, and a third source layer SL3 on the second source insulating layer SIL2.

The first source insulating layer SIL1 may be disposed between the first source layer SL1 and the second source layer SL2. The second source insulating layer SIL2 may be disposed between the second source layer SL2 and the third source layer SL3. The first to third source layers SL1, SL2 and SL3 may be spaced apart from each other.

The first to third source layers SL1, SL2 and SL3 may include a conductive material. For example, the first to third source layers SL1, SL2 and SL3 may include poly-silicon. The second source layer SL2 may be a common source line.

The first and second source insulating layers SIL1 and SIL2 may include an insulating material. For example, the first and second source insulating layers SIL1 and SIL2 may include an oxide.

The third gate stack structure GST3 may be provided on the source structure SST. The second gate stack structure GST2 may be provided on the third gate stack structure GST3. The first gate stack structure GST1 may be provided on the second gate stack structure GST2. However, the number of the gate stack structures GST1, GST2 and GST3 is not limited to the number illustrated in FIG. 2B. In certain example embodiments, the number of the gate stack structures GST1, GST2 and GST3 may be 2 or less or 4 or more.

The first gate stack structure GST1 may include first insulating patterns IP1 and first conductive patterns CP1, which are alternately stacked in a third direction D3. The third direction D3 may intersect the first direction DI and the second direction D2. For example, the third direction D3 may be a vertical direction perpendicular to the first direction D1 and the second direction D2.

The second gate stack structure GST2 may include second insulating patterns IP2 and second conductive patterns CP2, which are alternately stacked in the third direction D3.

The third gate stack structure GST3 may include third insulating patterns IP3 and third conductive patterns CP3, which are alternately stacked in the third direction D3. A lowermost one of the third insulating patterns IP3 may be in contact with the third source layer SL3 of the source structure SST.

The first to third insulating patterns IP1, IP2 and IP3 may include an insulating material. For example, the first to third insulating patterns IP1, IP2 and IP3 may include an oxide. The first to third conductive patterns CP1, CP2 and CP3 may include a conductive material. For example, the first to third conductive patterns CP1, CP2 and CP3 may include tungsten.

The memory channel structures CS may extend in the third direction D3 to penetrate the first gate stack structure GST1, the second gate stack structure GST2, the third gate stack structure GST3, the first source insulating layer SIL1, the second source insulating layer SIL2, the second source layer SL2 and the third source layer SL3.

Each of the memory channel structures CS may include an insulating capping layer 189, a channel layer 187 surrounding the insulating capping layer 189, and a memory layer ML surrounding the channel layer 187. The memory layer ML may penetrate the third source layer SL3. The channel layer 187 may penetrate the first and second source insulating layers SIL1 and SIL2, the second source layer SL2 and the memory layer ML.

The channel layer 187 may be in contact with the first source layer SL1, the first source insulating layer SIL1, the second source layer SL2 and the second source insulating layer SIL2. The first source layer SL1, the first source insulating layer SIL1, the second source layer SL2 and the second source insulating layer SIL2 may surround the channel layer 187. The memory layer ML may be in contact with the third source layer SL3 and the second source insulating layer SIL2. The second source insulating layer SIL2 may surround the memory layer ML.

The insulating capping layer 189 may include an insulating material. For example, the insulating capping layer 189 may include an oxide.

The channel layer 187 may include a conductive material. For example, the channel layer 187 may include poly-silicon. The channel layer 187 may be in contact with the first source layer SL1, the second source layer SL2, the first source insulating layer SIL1 and the second source insulating layer SIL2. The channel layer 187 may be electrically connected to the second source layer SL2. The channel layer 187 may be spaced apart from the third source layer SL3.

The memory layer ML may include a tunnel insulating layer 186, a data storing layer 183 surrounding the tunnel insulating layer 186, and a blocking layer 182 surrounding the data storing layer 183. The memory layer ML may be spaced apart from the first source layer SL1, the second source layer SL2 and the first source insulating layer SIL1.

The tunnel insulating layer 186 may include an insulating material. For example, the tunnel insulating layer 186 may include an oxide.

The data storing layer 183 may be configured to store data. In some example embodiments, the data storing layer 183 may include a ferroelectric material. For example, the ferroelectric material may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate. The data storing layer 183 of the memory channel structure CS may store and/or change data by using polarization switching of the ferroelectric material. In certain example embodiments, the data storing layer 183 may include a material capable of trapping charges. For example, the data storing layer 183 may include a nitride.

The blocking layer 182 may include an insulating material. For example, the blocking layer 182 may include at least one of an oxide or a nitride. The blocking layer 182 may be spaced apart from the second source layer SL2. The blocking layer 182 may be in contact with the third source layer SL3.

Each of the memory channel structures CS may further include a bit line pad 185 provided on the channel layer 187. The bit line pad 185 may include a conductive material. For example, the bit line pad 185 may include poly-silicon or a metal.

A first cover insulating layer 120 may be provided on the first gate stack structure GST1 and the memory channel structures CS. The first cover insulating layer 120 may include an insulating material. A second cover insulating layer 150 may be provided on the first cover insulating layer 120. The second cover insulating layer 150 may include an insulating material.

The separation structures DS may penetrate the first to third gate stack structures GST1, GST2 and GST3, the second source insulating layer SIL2 and the third source layer SL3. The separation structures DS may be spaced apart from each other in the first direction D1 with the memory channel structures CS interposed therebetween. The separation structures DS may extend in the second direction D2. The separation structure DS may be in contact with the second source layer SL2, the second source insulating layer SIL2 and the third source layer SL3. The separation structure DS may include an insulating material. In certain example embodiments, the separation structure DS may further include a conductive material.

The bit line contact 161 may be connected to the memory channel structure CS. The bit line contact 161 may penetrate the first cover insulating layer 120. The bit line 165 may be connected to the bit line contact 161. The bit line 165 may be disposed in the second cover insulating layer 150. The bit line 165 may extend in the second direction D2. The bit line contact 161 and the bit line 165 may include a conductive material.

The channel layer 187 may include a bottom surface 187_D in contact with the first source layer SL1. The bottom surface 187_D of the channel layer 187 may be in contact with the source structure SST. For example, the bottom surface 187_D of the channel layer 187 may be in contact with the first source layer SL1 of the source structure SST. The bottom surface 187_D of the channel layer 187 may be spaced apart from the memory layer ML. In certain example embodiments, the bottom surface 187_D of the channel layer 187 may be in contact with the first source insulating layer SIL1 of the source structure SST.

The channel layer 187 may include an interposed portion 187_IN protruding toward the third source layer SL3. For example, the interposed portion 187_IN of the channel layer 187 may protrude along a plane defined by the first direction D1 and the second direction D2. The interposed portion 187_IN of the channel layer 187 may be surrounded by the tunnel insulating layer 186 of the memory layer ML. The interposed portion 187_IN of the channel layer 187 may be spaced apart from the source structure SST. For example, the interposed portion 187_IN of the channel layer 187 may be spaced apart from the second source layer SL2 of the source structure SST. In some example embodiments, the insulating capping layer 189 may include a first portion disposed at the same level as the interposed portion 187_IN of the channel layer 187, and a second portion disposed at the same level as the second source layer SL2. A width W1 of the first portion of the insulating capping layer 189 in the first direction D1 may be equal to a width W2 of the second portion of the insulating capping layer 189 in the first direction D1.

The channel layer 187 may include a side surface 187_S connecting the bottom surface 187_D of the channel layer 187 and a bottom surface 187_IND of the interposed portion 187_IN. The side surface 187_S of the channel layer 187 may be in contact with the first and second source layers SL1 and SL2, the first and second source insulating layers SIL1 and SIL2, the tunnel insulating layer 186, the data storing layer 183 and the blocking layer 182. In some example embodiments, the side surface 187_S of the channel layer 187 may be substantially perpendicular to the bottom surface 187_D of the channel layer 187 and the bottom surface 187_IND of the interposed portion 187_IN. In certain example embodiments, the side surface 187_S of the channel layer 187 may be inclined. In some example embodiments, an angle between the side surface 187_S of the channel layer 187 and the bottom surface 187_D of the channel layer 187 may be greater than 90 degrees and less than 180 degrees.

The memory layer ML may include a bottom surface ML_D in contact with a top surface of the second source insulating layer SIL2. The memory layer ML may include an inner side surface ML_IS in contact with the side surface 187_S of the channel layer 187. The inner side surface ML_IS of the memory layer ML may include an inner side surface 182_IS of the blocking layer 182, an inner side surface 183_IS of the data storing layer 183, and an inner side surface 186_IS of the tunnel insulating layer 186. The inner side surface 182_IS of the blocking layer 182, the inner side surface 183_IS of the data storing layer 183 and the inner side surface 186_IS of the tunnel insulating layer 186 may be coplanar with each other.

The memory layer ML may include an outer side surface ML_OS in contact with the third source layer SL3. The outer side surface ML_OS of the memory layer ML may be inclined. For example, an angle between the outer side surface ML_OS of the memory layer ML and the bottom surface ML_D of the memory layer ML may be greater than 90 degrees and less than 180 degrees. In certain example embodiments, the outer side surface ML_OS of the memory layer ML may be substantially perpendicular to the top surface of the second source insulating layer SIL2.

The tunnel insulating layer 186 may include a first surface 186_S1 in contact with a top surface 187_INU of the interposed portion 187_IN of the channel layer 187, and a second surface 186_S2 in contact with the bottom surface 187_IND of the interposed portion 187_IN of the channel layer 187. The first surface 186_S1 and the second surface 186_S2 of the tunnel insulating layer 186 may be parallel to each other. The second surface 186_S2 of the tunnel insulating layer 186 may be spaced apart from the source structure SST.

A level of the bottom surface 187_D of the channel layer 187 may be lower than a level of a bottom surface DS_D of the separation structure DS. The level of the bottom surface DS_D of the separation structure DS may be lower than a level of the bottom surface ML_D of the memory layer ML. The level of the bottom surface ML_D of the memory layer ML may be higher than the level of the bottom surface 187_D of the channel layer 187. The level of the bottom surface ML_D of the memory layer ML may be higher than a level of a top surface of the first source layer SL1 and a level of a top surface of the second source layer SL2.

In semiconductor devices according to some example embodiments, a width of a lower portion of the memory layer ML may be relatively wide, and thus a critical dimension of the insulating capping layer 189 may be secured at the same level as the lower portion of the memory layer ML. Because the critical dimension of the insulating capping layer 189 is secured, electrical characteristics of the semiconductor device may be improved.

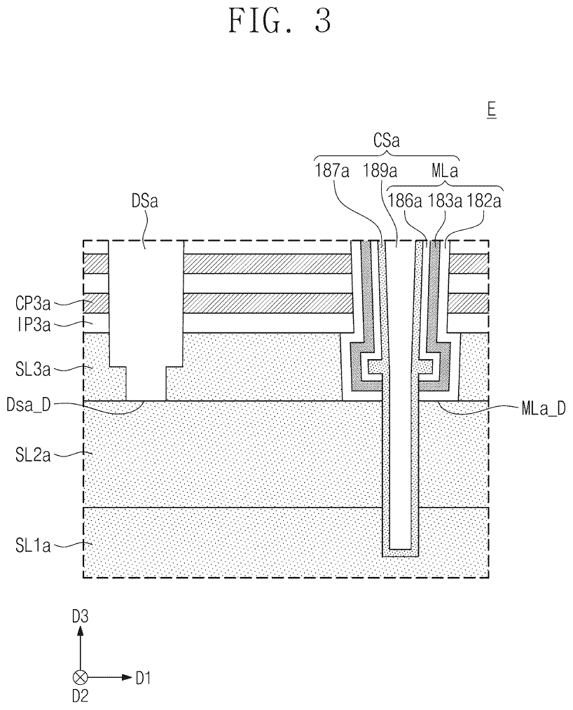

FIG. 3 is an enlarged view illustrating a semiconductor device according to an example embodiment of the inventive concepts.

Referring to FIG. 3, a source structure SSTa of a semiconductor device may include a first source layer SL1a, a second source layer SL2a, and a third source layer SL3a. A memory channel structure CSa may include an insulating capping layer 189a, a channel layer 187a, a tunnel insulating layer 186a, a data storing layer 183a, and a blocking layer 182a. The semiconductor device may include a separation structure DSa.

The memory channel structure CSa may penetrate the second source layer SL2a and the third source layer SL3a. The separation structure DSa may penetrate the third source layer SL3a.

The second source layer SL2a may be disposed between the first source layer SL1a and the third source layer SL3a. The first source layer SL1a may be in contact with the second source layer SL2a. The third source layer SL3a may be in contact with the second source layer SL2a.

A bottom surface MLa_D of a memory layer MLa may be in contact with a top surface of the second source layer SL2a. A bottom surface Dsa_D of the separation structure DSa may be in contact with the top surface of the second source layer SL2a. A level of the bottom surface MLa_D of the memory layer MLa may be the same as a level of the bottom surface Dsa_D of the separation structure DSa.

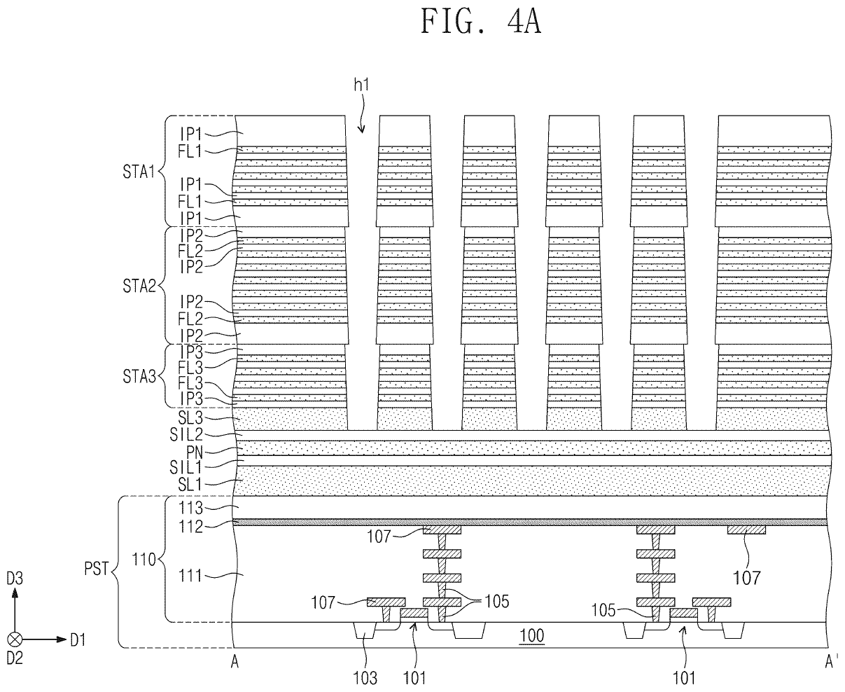

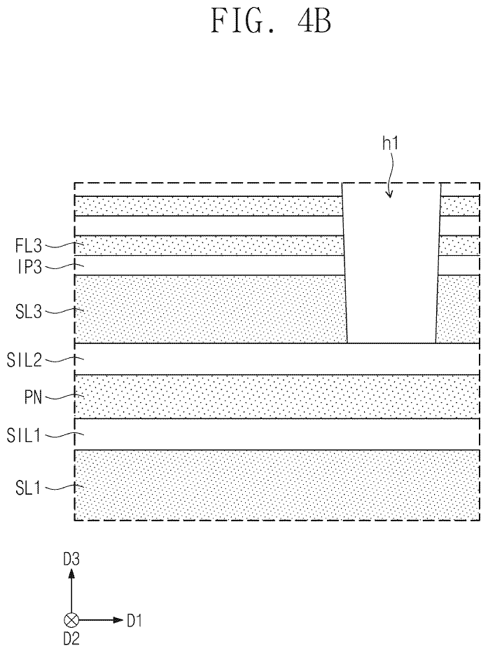

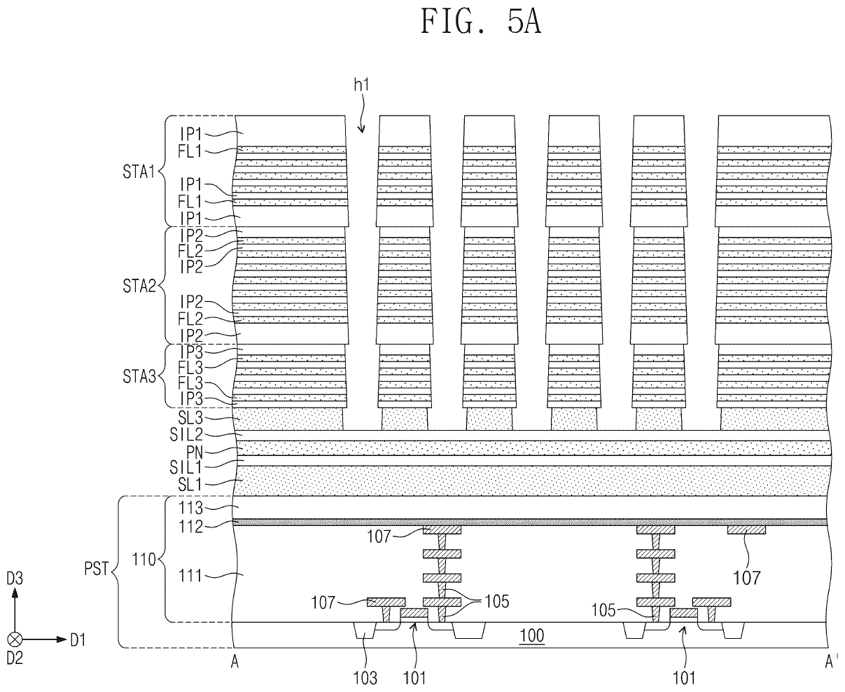

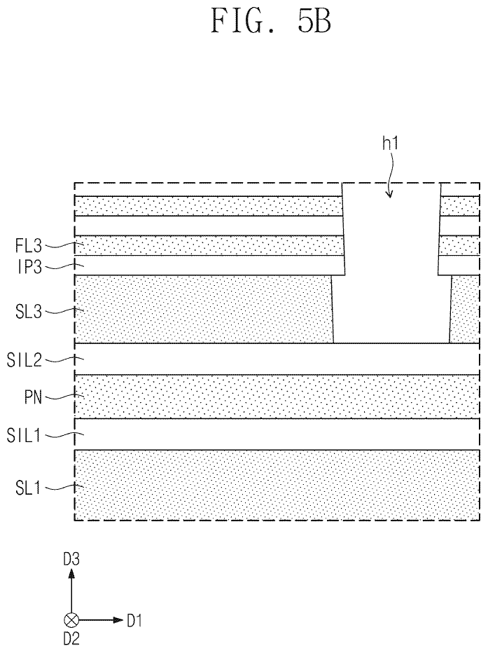

FIGS. 4A, 4B, 5A, 5B, 6A, 6B, 7A, 7B, 8A, 8B, 9A, 9B, 10A and 10B are views illustrating a method of manufacturing a semiconductor device according to s an example embodiment of the inventive concepts. FIGS. 4A, 5A, 6A, 7A, 8A, 9A and 10A may correspond to FIG. 2B. FIGS. 5B, 6B, 7B, 8B, 9B and 10B may correspond to FIG. 2C.

Referring to FIGS. 4A and 4B, a peripheral circuit structure PST, a first source layer SL1, a first source insulating layer SIL1, a sacrificial source layer PN, a second source insulating layer SIL2, a third source layer SL3, a first stack structure STA1, a second stack structure STA2 and a third stack structure STA3 may be formed on a substrate 100.

The first source layer SL1 may be formed on the peripheral circuit structure PST, the first source insulating layer SIL1 may be formed on the first source layer SL1, the sacrificial source layer PN may be formed on the first source insulating layer SIL1, the second source insulating layer SIL2 may be formed on the sacrificial source layer PN, and the third source layer SL3 may be formed on the second source insulating layer SIL2.

The first source insulating layer SIL1, the sacrificial source layer PN and the second source insulating layer SIL2 may include insulating materials. For example, the first source insulating layer SIL1 and the second source insulating layer SIL2 may include an oxide. For example, the sacrificial source layer PN may include a nitride. The first source layer SL1 and the third source layer SL3 may include a conductive material. For example, the first source layer SL1 and the third source layer SL3 may include poly-silicon.

The third stack structure STA3 may be formed on the third source layer SL3. The second stack structure STA2 may be formed on the third stack structure STA3. The first stack structure STA1 may be formed on the second stack structure STA2.

The first stack structure STA1 may include first insulating patterns IP1 and first sacrificial layers FL1, which are alternately stacked. The second stack structure STA2 may include second insulating patterns IP2 and second sacrificial layers FL2, which are alternately stacked. The third stack structure STA3 may include third insulating patterns IP3 and third sacrificial layers FL3, which are alternately stacked. The insulating patterns IP1, IP2 and IP3 may include an insulating material different from that of the sacrificial layers FL1, FL2 and FL3. For example, the insulating patterns IP1, IP2 and IP3 may include an oxide, and the sacrificial layers FL1, FL2 and FL3 may include a nitride.

A first opening h1 may be formed. The first to third stack structures STA1, STA2 and STA3 and the third source layer SL3 may define the first opening h1. The insulating patterns IP1, IP2 and IP3 and the sacrificial layers FL1, FL2 and FL3 of the first to third stack structures STA1, STA2 and STA3, the third source layer SL3 and the second source insulating layer SIL2 may be exposed by the first opening h1.

Referring to FIGS. 5A and 5B, a portion of the third source layer SL3 may be removed through the first opening h1. The first opening h1 may be expanded by the removal of the portion of the third source layer SL3. The first opening h1 may further include an empty space formed by the removal of the portion of the third source layer SL3. The first opening h1 may be expanded to expose a portion of a bottom surface of a lowermost one of the third insulating patterns IP3. In some example embodiments, the portion of the third source layer SL3 may be removed using a wet etching process.

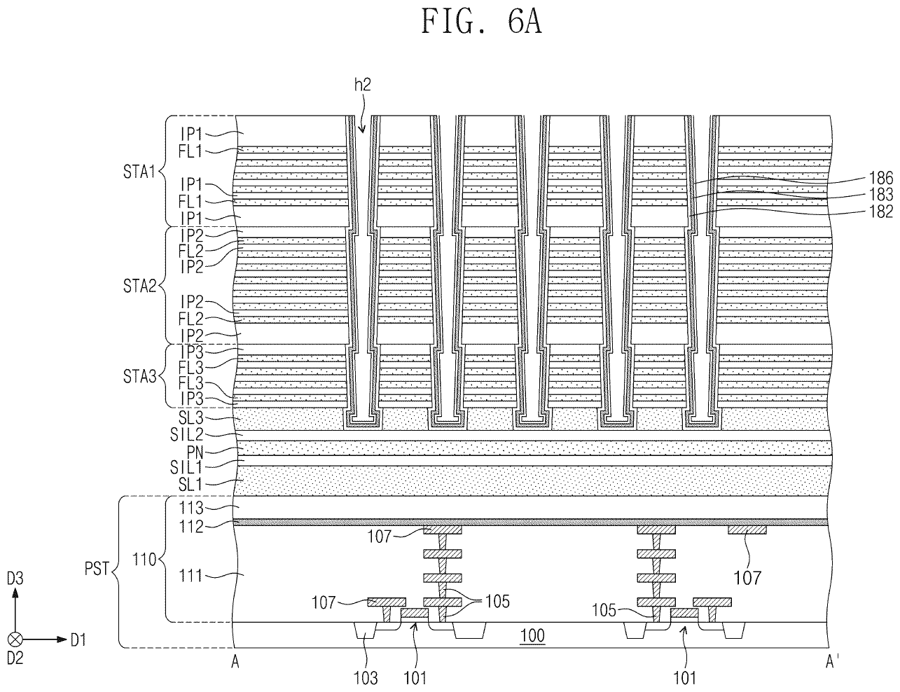

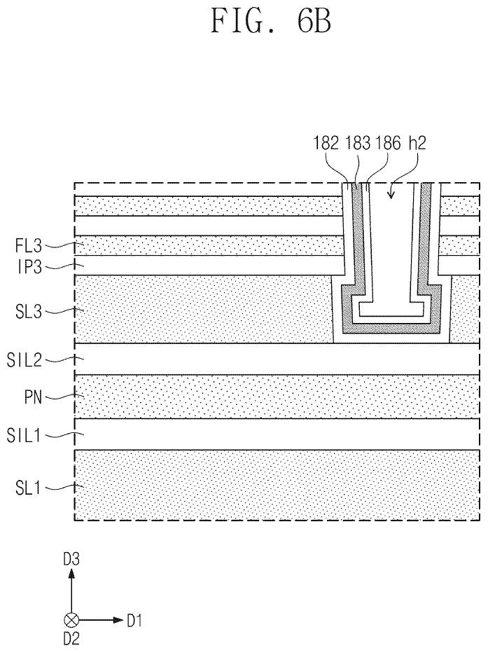

Referring to FIGS. 6A and 6B, a blocking layer 182, a data storing layer 183 and a tunnel insulating layer 186 may be formed on an inner surface of the first opening h1. The blocking layer 182 may cover the second source insulating layer SIL2 exposed through the first opening h1, the third source layer SL3 exposed through the first opening h1, and the first to third stack structures STA1, STA2 and STA3 exposed through the first opening h1. The data storing layer 183 may be formed on the blocking layer 182. The tunnel insulating layer 186 may be formed on the data storing layer 183. Because the blocking layer 182, the data storing layer 183 and the tunnel insulating layer 186 are formed on the inner surface of the first opening h1, a second opening h2 may be formed. The second opening h2 may be defined by an exposed surface of the tunnel insulating layer 186.

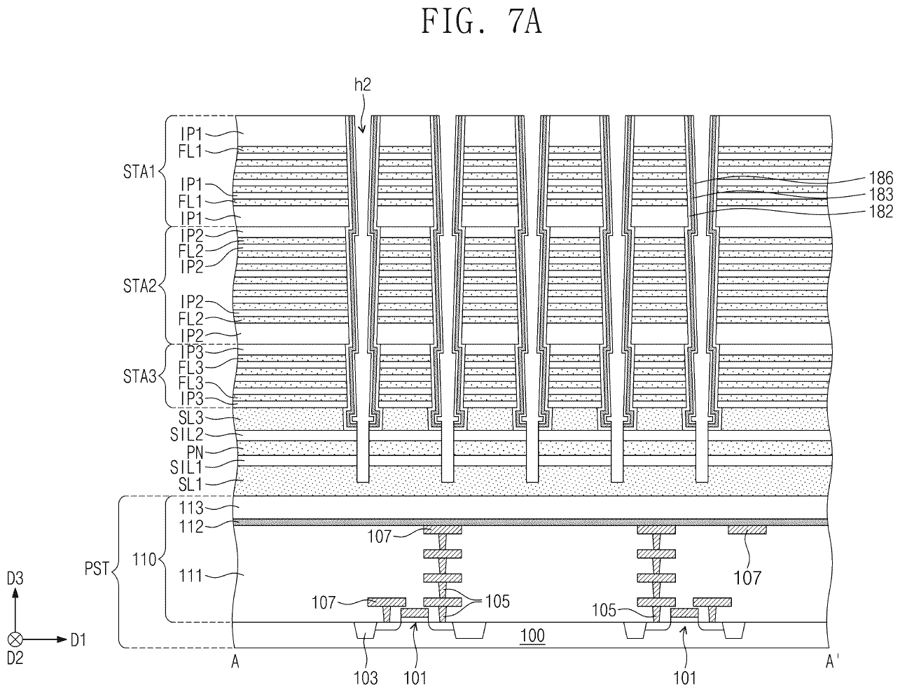

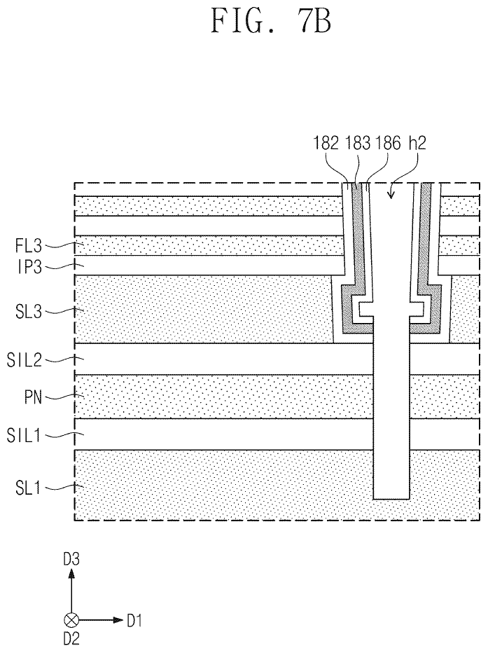

Referring to FIGS. 7A and 7B, the blocking layer 182, the data storing layer 183, the tunnel insulating layer 186, the first source layer SL1, the first source insulating layer SIL1, the sacrificial source layer PN, and the second source insulating layer SIL2 may be etched through the second opening h2.

The blocking layer 182, the data storing layer 183, the tunnel insulating layer 186, the first source layer SL1, the first source insulating layer SIL1, the sacrificial source layer PN, and the second source insulating layer SIL2 may be etched to extend the second opening h2. The extended second opening h2 may further include an empty space formed by the etching of the blocking layer 182, the data storing layer 183, the tunnel insulating layer 186, the first source layer SL1, the first source insulating layer SIL1, the sacrificial source layer PN, and the second source insulating layer SIL2. The blocking layer 182, the data storing layer 183, the tunnel insulating layer 186, the first source layer SL1, the first source insulating layer SIL1, the sacrificial source layer PN, and the second source insulating layer SIL2 may be exposed by the second opening h2.

In some example embodiments, the blocking layer 182, the data storing layer 183, the tunnel insulating layer 186, the first source layer SL1, the first source insulating layer SIL1, the sacrificial source layer PN, and the second source insulating layer SIL2 may be etched using a dry etching process.

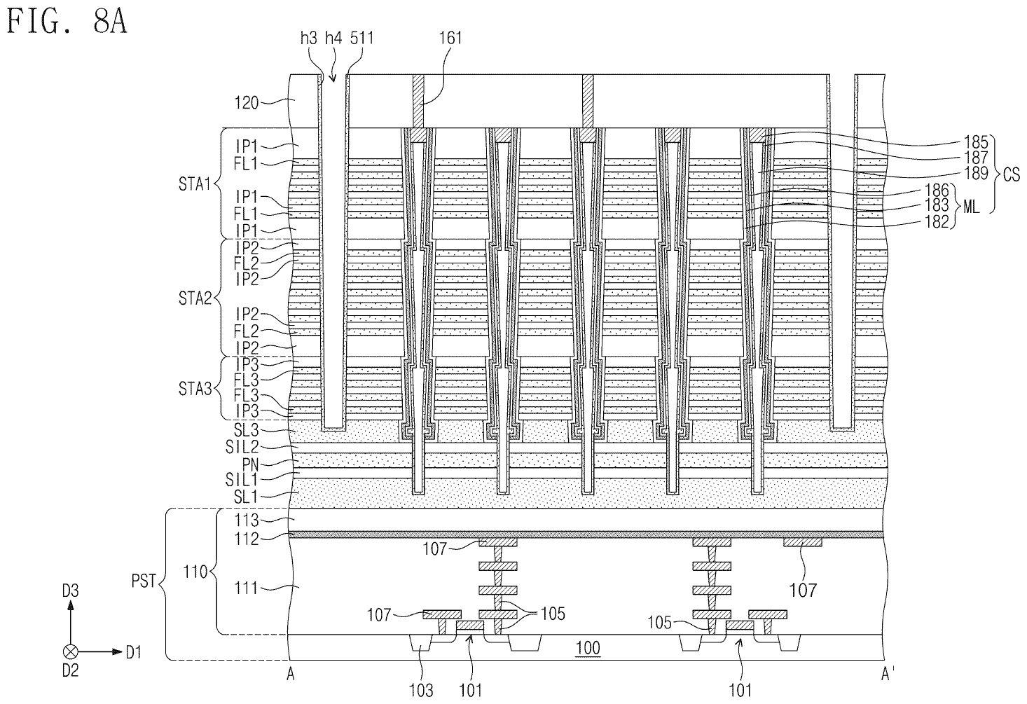

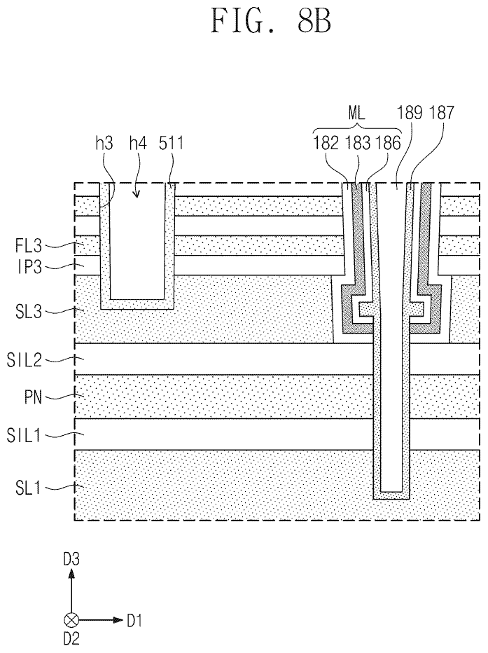

Referring to FIGS. 8A and 8B, a channel layer 187, an insulating capping layer 189 and a bit line pad 185 may be formed in the second opening h2. A memory channel structure CS may be defined by the formation of the channel layer 187, the insulating capping layer 189 and the bit line pad 185. A first cover insulating layer 120 may be formed on the first stack structure STA1 and the memory channel structure CS. A bit line contact 161 may be formed to penetrate the first cover insulating layer 120, and the bit line contact 161 may be connected to the bit line pad 185 of the memory channel structure CS.

The third source layer SL3, the first to third stack structures STA1, STA2 and STA3 and the first cover insulating layer 120 may be etched to form a third opening h3. In some example embodiments, the third source layer SL3, the first to third stack structures STA1, STA2 and STA3 and the first cover insulating layer 120 may be etched using a dry etching process. The third source layer SL3, the first to third stack structures STA1, STA2 and STA3 and the first cover insulating layer 120 may be exposed by the third opening h3. A barrier layer 511 may be formed in the third opening h3. The barrier layer 511 may be formed on the third source layer SL3, the first to third stack structures STA1, STA2 and STA3 and the first cover insulating layer 120 that are exposed by the third opening h3.

A fourth opening h4 may be formed by the formation of the barrier layer 511. The fourth opening h4 may be defined by a surface of the barrier layer 511. The barrier layer 511 may include a conductive material. For example, the barrier layer 511 may include poly-silicon.

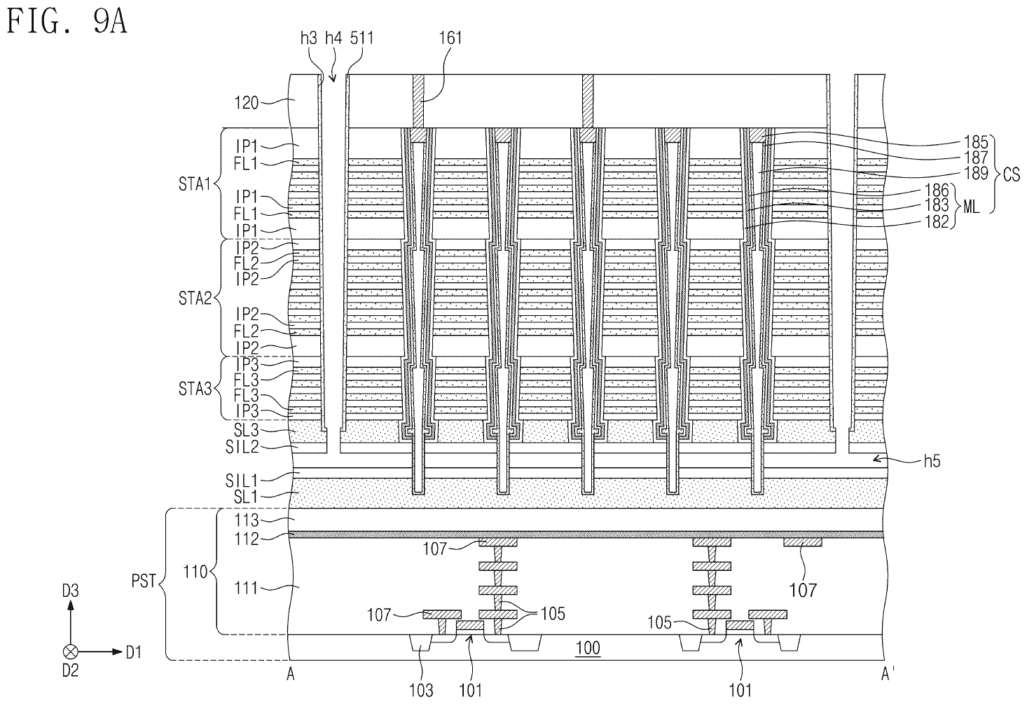

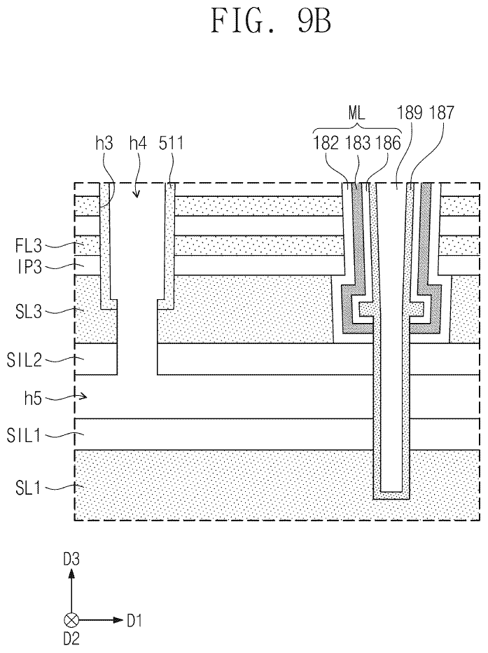

Referring to FIGS. 9A and 9B, a portion of the barrier layer 511, a portion of the third source layer SL3, a portion of the second source insulating layer SIL2 and an entirety of the sacrificial source layer PN may be removed through the fourth opening h4.

A fifth opening h5 may be formed by the removal of the sacrificial source layer PN. A top surface of the first source insulating layer SIL1, a bottom surface of the second source insulating layer SIL2 and the channel layer 187 of the memory channel structure CS may be exposed by the fifth opening h5.

In some example embodiments, the portion of the barrier layer 511, the portion of the third source layer SL3 and the portion of the second source insulating layer SIL2 may be removed using a dry etching process. In some example embodiments, the sacrificial source layer PN may be removed using a wet etching process.

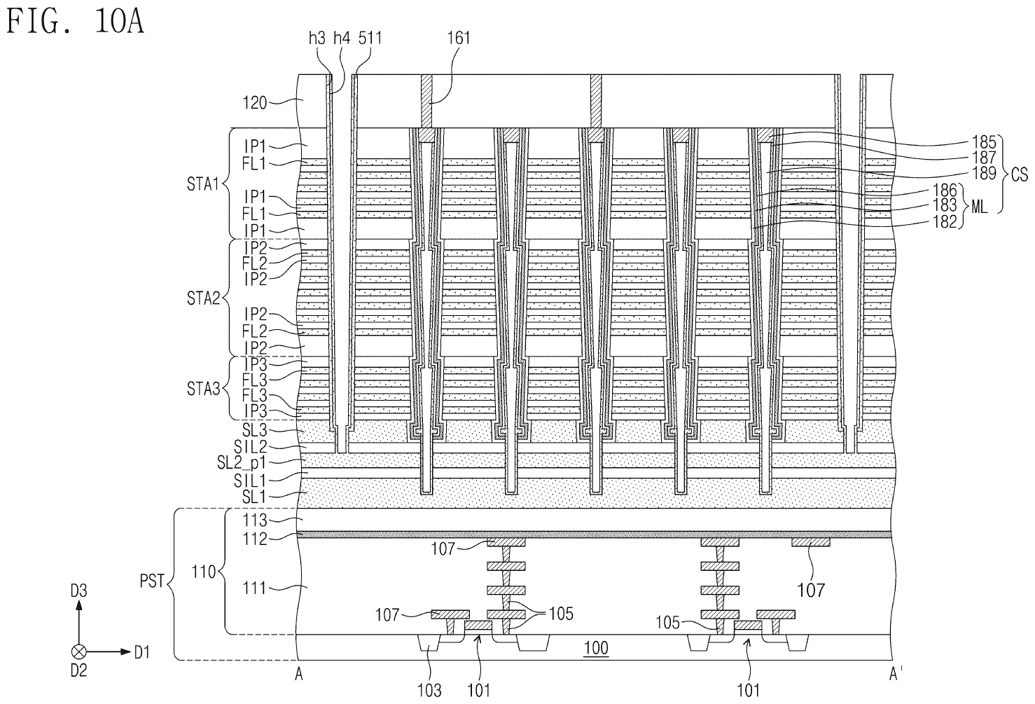

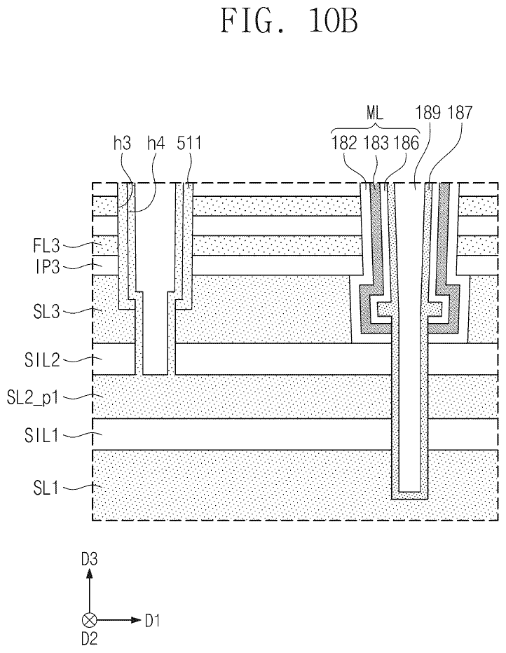

Referring to FIGS. 10A and 10B, a preliminary source layer SL2_p1 may be formed in the fourth opening h4 and the fifth opening h5. The preliminary source layer SL2_p1 may fill a portion of the fourth opening h4 and an entirety of the fifth opening h5. The preliminary source layer SL2_p1 may cover the barrier layer 511, the first source insulating layer SIL1, the second source insulating layer SIL2 and the third source layer SL3. The preliminary source layer SL2_p1 may include a conductive material. For example, the preliminary source layer SL2_p1 may include poly-silicon.

Referring again to FIGS. 2B and 2C, a portion of the preliminary source layer SL2_p1 in the fourth opening h4 and the barrier layer 511 may be removed. The portion of the preliminary source layer SL2_p1 in the fourth opening h4 may be removed to form a second source layer SL2. A source structure SST may be defined by the formation of the second source layer SL2.

The third opening h3 may be opened by the removal of the portion of the preliminary source layer SL2_p1 in the fourth opening h4 and the barrier layer 511. The sacrificial layers FL1, FL2 and FL3 of the first to third stack structures STA1, STA2 and STA3 may be exposed through the third opening h3. The exposed sacrificial layers FL1, FL2 and FL3 may be removed. Empty spaces formed by the removal of the sacrificial layers FL1, FL2 and FL3 may be filled with a conductive material, thereby forming conductive patterns CP1, CP2 and CP3. First to third gate stack structures GST1, GST2 and GST3 may be defined by the formation of the conductive patterns CP1, CP2 and CP3.

After the formation of the conductive patterns CP1, CP2 and CP3, a separation structure DS may be formed in the third opening h3. The separation structure DS may fill the third opening h3. After the formation of the separation structures DS, a second cover insulating layer 150 and bit lines 165 may be formed on the separation structures DS and the bit line contacts 161.

The method of manufacturing a semiconductor device according to the example embodiments may not include a process of etching the blocking layer 182, the data storing layer 183 and the tunnel insulating layer 186 after the formation of the channel layer 187 and the insulating capping layer 189. Thus, process difficulty may be reduced.

In the semiconductor device and the electronic system including the same according to some example embodiments of the inventive concepts, the channel layer may include the interposed portion, and thus a substantially uniform width of the insulating capping layer may be secured to improve the electrical characteristics of the semiconductor device.

While some example embodiments of the inventive concepts have been particularly shown and described, it will be understood by one of ordinary skill in the art that variations in form and detail may be made therein without departing from the spirit and scope of the attached claims.

What is claimed is:

1. A semiconductor device comprising:
a source structure comprising a first source layer, a second source layer on the first source layer, and a third source layer on the second source layer;
a gate stack structure on the source structure, the gate stack structure with alternating insulating patterns and conductive patterns; and
a memory channel structure penetrating the gate stack structure,
wherein the memory channel structure comprises a channel layer and a memory layer surrounding the channel layer,
wherein the channel layer penetrates the memory layer and the second source layer, and
wherein a bottom surface of the channel layer is in contact with the source structure.

2. The semiconductor device of claim 1, wherein the source structure further comprises:
a first source insulating layer between the first source layer and the second source layer; and
a second source insulating layer between the second source layer and the third source layer.

3. The semiconductor device of claim 2, wherein the channel layer of the memory channel structure further penetrates the first source insulating layer and the second source insulating layer.

4. The semiconductor device of claim 2, wherein a top surface of the second source insulating layer is in contact with a bottom surface of the memory layer.

5. The semiconductor device of claim 1, wherein the memory layer of the memory channel structure is spaced apart from the second source layer.

6. The semiconductor device of claim 1, wherein
the memory layer of the memory channel structure comprises,
a tunnel insulating layer surrounding the channel layer,
a data storing layer surrounding the tunnel insulating layer, and
a blocking layer surrounding the data storing layer, and
the data storing layer includes a ferroelectric material.

7. The semiconductor device of claim 1, wherein
the channel layer includes an interposed portion protruding toward the third source layer, and
the interposed portion of the channel layer is spaced apart from the source structure.

8. The semiconductor device of claim 7, wherein the interposed portion of the channel layer is spaced apart from the second source layer.

9. The semiconductor device of claim 1, wherein the second source layer is spaced apart from the first source layer.

10. The semiconductor device of claim 1, wherein the memory layer of the memory channel structure is spaced apart from the first source layer.

11. The semiconductor device of claim 1, wherein the bottom surface of the channel layer is in contact with the first source layer.

12. A semiconductor device comprising:
a source structure comprising a first source layer, a second source layer on the first source layer, and a third source layer on the second source layer;
a gate stack structure on the source structure, the gate stack structure with alternating insulating patterns and conductive patterns; and
a memory channel structure penetrating the gate stack structure,
wherein the memory channel structure comprises a channel layer and a memory layer surrounding the channel layer, and
wherein the channel layer includes an interposed portion protruding toward the third source layer and a bottom surface spaced apart from the memory layer.

13. The semiconductor device of claim 12, wherein
the channel layer includes a side surface connecting a bottom surface of the interposed portion and the bottom surface of the channel layer, and
the side surface of the channel layer is in contact with the first source layer and the second source layer.

14. The semiconductor device of claim 12, wherein a level of a bottom surface of the memory layer is higher than a level of the bottom surface of the channel layer.

15. The semiconductor device of claim 12, wherein the second source layer is spaced apart from the third source layer.

16. The semiconductor device of claim 12, wherein
the source structure further comprises:
a first source insulating layer between the first source layer and the second source layer; and
a second source insulating layer between the second source layer and the third source layer, and
the channel layer is in contact with the first source insulating layer and the second source insulating layer.

17. The semiconductor device of claim 16, wherein the first source insulating layer and the second source insulating layer surround the channel layer of the memory channel structure.

18. The semiconductor device of claim 12, wherein the channel layer of the memory channel structure penetrates the memory layer and the second source layer.

19. An electronic system comprising:
a main board;
a semiconductor device on the main board; and
a controller electrically connected to the semiconductor device on the main board,
wherein the semiconductor device comprises,
a source structure comprising a first source layer, a second source layer on the first source layer, and a third source layer on the second source layer,
a gate stack structure on the source structure, the gate stack structure with alternating insulating patterns and conductive patterns,
a memory channel structure penetrating the gate stack structure, and
a separation structure spaced apart from the memory channel structure,
wherein the memory channel structure comprises a channel layer and a memory layer surrounding the channel layer,
wherein the memory layer comprises,
a tunnel insulating layer,
a data storing layer surrounding the tunnel insulating layer, and
a blocking layer surrounding the data storing layer, and
wherein a level of a bottom surface of the memory layer is higher than a level of a bottom surface of the separation structure.

20. The electronic system of claim 19, wherein
the source structure further comprises,
a first source insulating layer between the first source layer and the second source layer, and
a second source insulating layer between the second source layer and the third source layer, and
the separation structure penetrates the second source insulating layer.
